(19) United States
(12) Patent Application Publication
(10) Pub. No.: US 2017/0186719 A1
(43) Pub. Date: Jun. 29, 2017

(54) SEMICONDUCTOR DEVICE, METHOD OF MANUFACTURING SAME, AND ELECTRONIC APPARATUS

(71) Applicant: FUJITSU LIMITED, Kawasaki-shi (JP)

(72) Inventors: Hidehiko Kira, Nagano (JP); Naoaki Nakamura, Kawasaki (JP); TAKASHI KUBOTA, Chikuma (JP)

(73) Assignee: FUJITSU LIMITED, Kawasaki-shi (JP)

(21) Appl. No.: 15/368,755

(22) Filed: Dec. 5, 2016

(30) Foreign Application Priority Data
Dec. 28, 2015 (JP) 2015-255639

(51) Int. Cl. H01L 23/00; H01L 25/065; H01L 21/56; H01L 25/00; H01L 21/48; H01L 23/498; H01L 23/18

(52) U.S. Cl. CPC H01L 24/32; H01L 23/49811; H01L 23/49833; H01L 25/0657; H01L 23/49838; H01L 23/18; H01L 25/50; H01L 21/4803; H01L 21/563; H01L 24/73; H01L 24/16; H01L 2225/06513; H01L 2225/06541; H01L 2224/73204; H01L 2224/16238; H01L 2224/16148; H01L 2224/32145; H01L 2224/32225; H01L 2924/15151; H01L 2924/1816; H01L 2924/18301; H01L 2224/26175; H01L 2224/26145

(57) ABSTRACT

A semiconductor device includes a first substrate, a second substrate, a connection portion, and resin. The second substrate faces the first substrate, and has a recess at a position corresponding to an edge portion of the first substrate. The connection portion is interposed between the first substrate and the second substrate, and electrically connects the first substrate and the second substrate. Resin is disposed to remain between the first substrate and the second substrate, and covers the connection portion. Part of the resin is present in the recess of the second substrate. The recess serves as a resin reservoir for resin that is caused to flow upon bonding, and prevents the resin from flowing along a side surface of the first substrate to a back surface thereof, thereby preventing contamination by the resin.

### CROSS-REFERENCE TO RELATED APPLICATION

This application is based upon and claims the benefit of priority of the prior Japanese Patent Application No. 2015-255639, filed on Dec. 28, 2015, the entire contents of which are incorporated herein by reference.

### FIELD

The embodiments discussed herein are related to a semiconductor device, a method of manufacturing the same, and an electronic apparatus.

### BACKGROUND

Techniques for stacking a plurality of semiconductor chips are known. In connection with these techniques, there has been proposed a method that, after forming a chip stack structure including a plurality of stacked semiconductor chips, supplies resin such as an underfill material and the like having flowability, covers the periphery of the chip stack structure with the resin, and fills gaps between the semiconductor chips with the resin, for example. There has also been proposed a method that mounts a composite chip stack structure obtained in the manner described above on a wiring board with resin such as a non-conductive paste (NCP) and the like applied thereon, electrically connects the composite chip stack structure and the wiring board by thermocompression bonding or the like, and bonds the composite chip stack structure and the wiring board with the resin.

See, for example, Japanese Laid-open Patent Publication No. 2014-7228.

However, with the method that bonds various types of substrates such as a semiconductor chip and a wiring board with resin interposed therebetween by thermocompression bonding or the like, as pressure is applied, the resin often flows out to the side surfaces of the substrates, and further to a surface (back surface) opposite to the bonding surface (front surface), resulting in contamination by resin. Such contamination by resin may affect the quality of a substrate bonded structure and a semiconductor device including the substrate bonded structure. For example, a terminal on the back surface of a substrate is covered with resin, so that poor bonding may occur when bonding a terminal of another substrate to that terminal.

### SUMMARY

According to an aspect, there is provided a semiconductor device including: a first substrate; a second substrate facing the first substrate, and having a recess at a position corresponding to an edge portion of the first substrate; a connection portion interposed between the first substrate and the second substrate, and electrically connecting the first substrate and the second substrate; and resin disposed to remain between the first substrate and the second substrate, and covering the connection portion, part of the resin being present in the recess.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B illustrate an example of a form of bonding;

FIG. 2 illustrates another example of a form of bonding;

FIG. 3 illustrates an example of a semiconductor device according to a first embodiment;

FIGS. 4A, 4B, 5, 6, 7A, 7B, and 7C illustrate a method of forming a semiconductor device according to the first embodiment;

FIGS. 8A and 8B illustrate an example of the configuration of a semiconductor chip;

FIGS. 9A to 9C illustrate an example of a method of forming a semiconductor chip;

FIG. 10 illustrates an example of the configuration of an interposer;

FIGS. 11A to 11D illustrate the shape of a recess;

FIGS. 12A to 12C illustrate the arrangement of a recess;

FIG. 13 illustrates an example of a semiconductor device according to a second embodiment;

FIGS. 14A to 14C illustrate an example of a process of forming a semiconductor device according to the second embodiment;

FIG. 15 illustrates an example of a semiconductor device according to a third embodiment;

FIGS. 16A to 16C illustrate another example of a semiconductor device according to the third embodiment;

FIGS. 17A and 17B illustrate an example of a semiconductor device according to a fourth embodiment;

FIGS. 18A to 18C illustrate an example of a process of forming a semiconductor device according to the fourth embodiment;

FIG. 19 illustrates an example of a semiconductor device according to a fifth embodiment;

FIG. 20 illustrates an example of a semiconductor device according to a sixth embodiment;

FIGS. 21A to 21C illustrate an example of a process of forming a semiconductor device according to the sixth embodiment; and

FIG. 22 illustrates an example of an electronic apparatus.

### DESCRIPTION OF EMBODIMENTS

Several embodiments will be described below with reference to the accompanying drawings, wherein like reference numerals refer to like elements throughout.

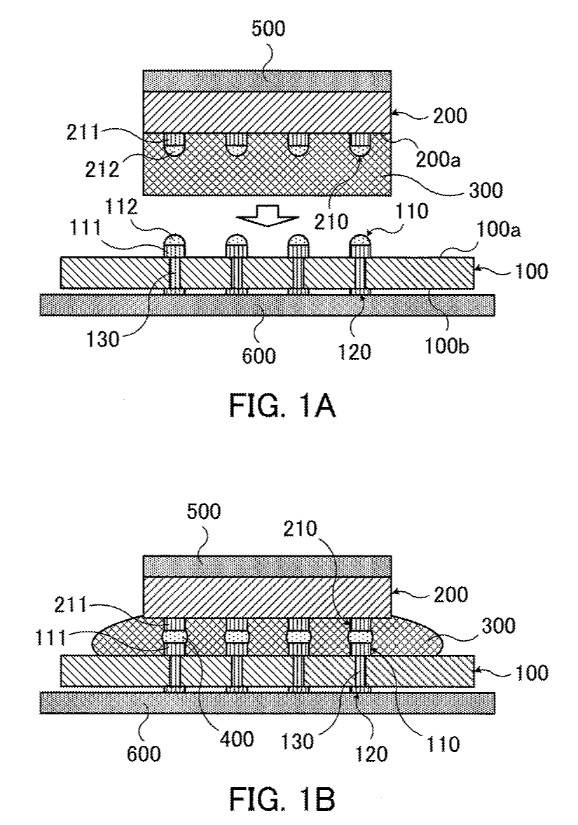

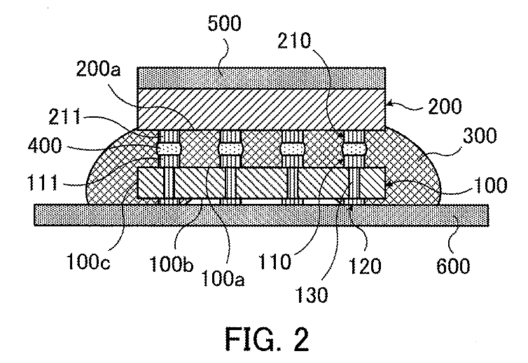

First, one form of bonding substrates together will be described with reference to FIGS. 1A, 1B, and 2.

FIGS. 1A and 1B illustrate an example of a form of bonding. More specifically, FIG. 1A is a schematic cross-sectional view illustrating an example of a main part before bonding, and FIG. 1B is a schematic cross-sectional view illustrating an example of the main part after bonding. Further, FIG. 2 illustrates another example of a form of bonding. More specifically, FIG. 2 is a schematic cross-sectional view illustrating another example of a main part after bonding.

A lower substrate 100 illustrated in FIG. 1A is, for example, a semiconductor chip, a wafer before dicing into semiconductor chips, or a circuit board such as an interposer, a printed board, and the like. The substrate 100 includes a terminal 110 on one surface (front surface) 100a thereof, and a terminal 120 on a surface (back surface) 100b opposite to the front surface 100a. In this example, the substrate 100 includes a plurality of terminals 110 and a plurality of terminals 120. Further, in this example, each terminal 110 on the front surface 100a includes a post (pillar) 111 disposed to protrude from the front surface 100a, and a solder 112 at the distal end of the post 111. On the other hand, each terminal 120 on the back surface 100b is a pad. The terminal 110 and the terminal 120 are electrically connected through a conductor 130 disposed inside the substrate 100. The conductor 130 is formed using a through-silicon via (TSV) forming technique, a through hole forming technique, or the like, for example.

An upper substrate 200 illustrated in FIG. 1A is, for example, a semiconductor chip, a wafer, or a circuit board. The substrate 200 includes a terminal 210 on a surface (front surface) 200a facing the surface of the lower substrate 100 on which the terminals 110 are disposed. In this example, the substrate 200 includes a plurality of terminals 210. The terminals 210 of the substrate 200 are disposed at the positions corresponding to the terminals 110 of the substrate 100. Further, in this example, each terminal 210 includes a post 211 disposed to protrude from the front surface 200a, and a solder 212 disposed at the distal end of the post 211. In this example, the lower substrate 100 has a planar size (an external size in a plan view) greater than that of the upper substrate 200.

As illustrated in FIG. 1A, before bonding the substrate 100 and the substrate 200, resin 300 is disposed between the substrate 100 and the substrate 200 (for example, on the front surface 200a of the substrate 200). A paste resin material such as NCP or a film resin material such as a non-conductive film (NCF) is used as the resin 300.

As illustrated in FIG. 1B, when bonding the substrate 100 and the substrate 200, the upper substrate 200 is sucked and held by a bonding tool (head) 500, and the lower substrate 100 is sucked and held on a suction stage (stage) 600. The upper substrate 200 is pressed toward the lower substrate 100 with pressure applied thereto, while being heated. In this step, as the pressure is applied, the terminals 210 of the substrate 200 penetrate the resin 300. The solders 212 of the terminals 210 come into contact with the corresponding solders 112 of the terminals 110 of the substrate 100, and are melted and integrated therewith by heat. Thus, solder bonding portions 400 are formed. Further, the resin 300 is cured by heat applied during formation of the solder bonding portions 400, or by a curing process (application of heat, irradiation of light such as ultraviolet, or the like) after formation of the solder bonding portions 400. As a result, the substrate 100 and the substrate 200 are electrically and mechanically connected through the posts 111, the solder bonding portions 400, and the posts 211. Further, the resin 300 enhances the bonding strength between the substrate 100 and the substrate 200.

When bonding the substrate 100 and the substrate 200, pressure is applied for bonding, so that the substrate 100 and the substrate 200 are brought closer to each other until the gap therebetween is reduced to a certain distance. Thus, as illustrated in FIG. 1B, the excess resin 300 is pushed out from the gap between the substrate 100 and the substrate 200.

FIGS. 1A and 1B illustrate an example of bonding in the case where the lower substrate 100 has a planar size greater than that of the upper substrate 200. On the other hand, in the case where the lower substrate 100 has a planar size equal to or smaller than that of the upper substrate 200, a situation illustrated in FIG. 2 may occur.

FIG. 2 illustrates an example of the case where a lower substrate 100 has the same planar size as an upper substrate 200. For example, the substrate 200 with resin 300 disposed on a front surface 200a as illustrated in FIG. 1A is bonded to the substrate 100 having the same planar size as the substrate 200, by application of heat and pressure. Thus, similar to the above case, posts 111 and posts 211 are bonded with solder bonding portions 400, and the excess resin 300 resulting from bringing the substrate 100 and the substrate 200 closer to each other is pushed out from the gap between the substrate 100 and the substrate 200.

However, in the case where the lower substrate 100 has the same planar size as the upper substrate 200 as illustrated in FIG. 2, the excess resin 300 pushed out from the gap therebetween may flow to a side surface 100c of the substrate 100, and then flow along the side surface 100c to a back surface 100b. For example, in some cases, a gap is inevitably created between the substrate 100 and the stage 600 that sucks and holds the substrate 100 due to the structure of the back surface 100b. The gap and the suction force of the stage 600 may cause the resin 300 to flow to the back surface 100b (the resin 300 to flow into the gap between the back surface 100b and the stage 600).

The flow of the resin 300 to the back surface 100b of the substrate 100 and contamination of the back surface 100b of the substrate 100 by the resin 300 may affect the manufacture and quality of a semiconductor device including a bonded (stacked) structure of the substrate 100 and the substrate 200.

For example, terminals 120 on the back surface 100b of the substrate 100 may be covered with the resin 300 having flowed to the back surface 100b. In the case where the terminals 120 on the back surface 100b are covered with the resin 300, when terminals of another substrate are bonded to the terminals 120, electrical connection therebetween may be inhibited by the resin 300, resulting in poor bonding. In order to avoid such poor bonding, a process of removing the resin 300 covering the terminals 120 may be added before bonding of the terminals 120 and the terminals of the other substrate. However, this may cause a reduction in manufacturing efficiency due to increased man-hours, and an increase in manufacturing cost.

In view of the foregoing, contamination by resin is prevented by using the techniques described below as embodiments.

First, a first embodiment will be described.

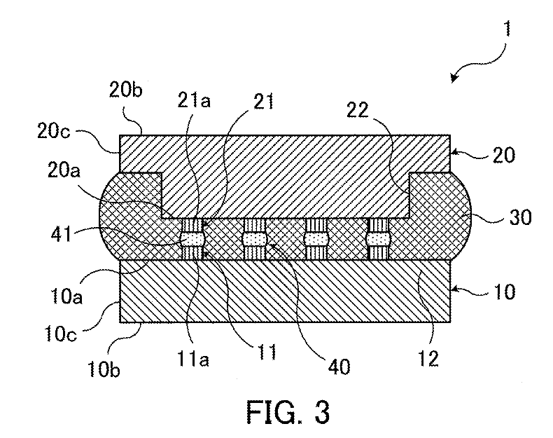

FIG. 3 illustrates an example of a semiconductor device according to the first embodiment. More specifically, FIG. 3 is a schematic cross-sectional view of a main part illustrating an example of a semiconductor device according to the first embodiment.

A semiconductor device 1 illustrated in FIG. 3 includes a lower substrate 10, an upper substrate 20, and resin 30 disposed between the substrate 10 and 20.

The lower substrate 10 is, for example, a semiconductor chip, a wafer before dicing into semiconductor chips, or a circuit board such as an interposer and the like. The substrate 10 includes a terminal 11 on one surface (front surface) 10a thereof. In this example, the substrate 10 includes a plurality of terminals 11. Further, in this example, each terminal 11 on the front surface 10a includes a post 11a disposed to protrude from the front surface 10a. The post 11a may be made of a material such as copper (Cu), nickel (Ni), gold (Au), and so on.

Note that the lower substrate 10 may include a plurality of terminals such as pads, for example, on a surface (back surface) 10b opposite to the front surface 10a. In this case, each terminal 11 on the front surface 10a and the corresponding terminal on the back surface 10b may be electrically connected through a conductor disposed inside the substrate 10. The conductor is formed using a TSV forming technique, a through hole forming technique, or the like.

The upper substrate 20 is, for example, a semiconductor chip, a wafer before dicing into semiconductor chips, or a circuit board such as an interposer and the like. The substrate 20 includes a terminal 21 on a surface (front surface) 20a facing the surface of the lower substrate 10 on which the terminals are disposed. In this example, the substrate 20 includes a plurality of terminals 21. The terminals 21 of the substrate 20 are disposed at the positions corresponding to the terminals 11 of the substrate 10. Further, in this example, each terminal 21 includes a post 21a disposed to protrude from the front surface 20a. The post 21a may be made of a material such as Cu, Ni, Au, and so on.

Note that the upper substrate 20 may include a plurality of terminals such as pads, or a plurality of terminals including posts, for example, on a surface (back surface) 20b opposite to the front surface 20a. In this case, each terminal 21 on the front surface 20a and the corresponding terminal on the back surface 20b may be electrically connected through a conductor disposed inside the substrate 20. The conductor is formed using a TSV forming technique, a through hole forming technique, or the like.

In the semiconductor device 1, the lower substrate 10 has a planar size (an external size in a plan view) equal to or smaller than that of the upper substrate 20, for example. In this example, the lower substrate 10 and the upper substrate 20 have the same planar size.

The upper substrate 20 has a bottomed recess 22 (cutout). The recess 22 is provided at the position corresponding to an edge portion 12 of the lower substrate 10, in the front surface 20a facing the lower substrate 10. The edge portion 12 of the substrate 10 is, for example, a portion on the outer side of the area where the terminals are disposed. In the substrate 20, the recess 22 is provided at the position corresponding to the edge portion of the substrate 10. The recess 22 has a shape that extends to a side surface 20c of the substrate 20, for example. The recess 22 is provided at the entire peripheral edge portion of the substrate 20, for example. The terminals 21 of the substrate 20 are disposed in the area on the inner side of the recess 22 provided at the entire peripheral edge portion, for example.

As illustrated in FIG. 3, the terminals 11 (posts 11a) of the substrate 10 and the terminals 21 (posts 21a) of the substrate 20 are bonded with solder bonding portions 41. The solder bonding portions 41 may be made of solder containing tin (Sn). Examples of materials of the solder of the solder bonding portions 41 include: Sn solder; Sn—Ag solder containing Sn and Silver (Ag); Sn—Ag—Cu solder containing Sn, Ag, and Cu; Sn—In solder containing Sn and indium (In); Sn—Bi solder containing Sn and bismuth (Bi); and so on. The substrate 10 and the substrate 20 are electrically and mechanically connected through connection portions 40 each including one post 11a, one solder bonding portion 41, and one post 21a.

The resin 30 is disposed between the substrate 10 and the substrate 20 connected through the connection portions 40. The resin 30 is disposed to remain between the substrate 10 and the substrate 20 such that at least a part of a side surface 10c of the substrate 10 and at least a part of a side surface 20c of the substrate 20 are exposed. The connection portions 40 are covered with the resin 30. Various resin materials having insulating properties (for example, epoxy resin) may be used as the resin 30. The resin 30 may contain filler having insulating properties. The resin 30 may be formed using a paste resin material such as NCP or a film resin material such as NCF. The resin 30 enhances the bonding strength between the substrate 10 and the substrate 20 bonded with the connection portions 40.

Part of the resin 30 is present in the recess 22 of the upper substrate 20. When bonding the substrate 10 and the substrate 20 with the resin 30 as will be described below, part of the resin 30 that is caused to flow by application of pressure flows into the recess 22. The recess 22 serves as a resin reservoir into which part of the resin 30 flows upon bonding. In the semiconductor device 1, since part of the resin 30 flows into the recess upon bonding the lower substrate 10 and the upper substrate 20, the resin 30 is prevented from flowing to the back surface 10b of the lower substrate 10.

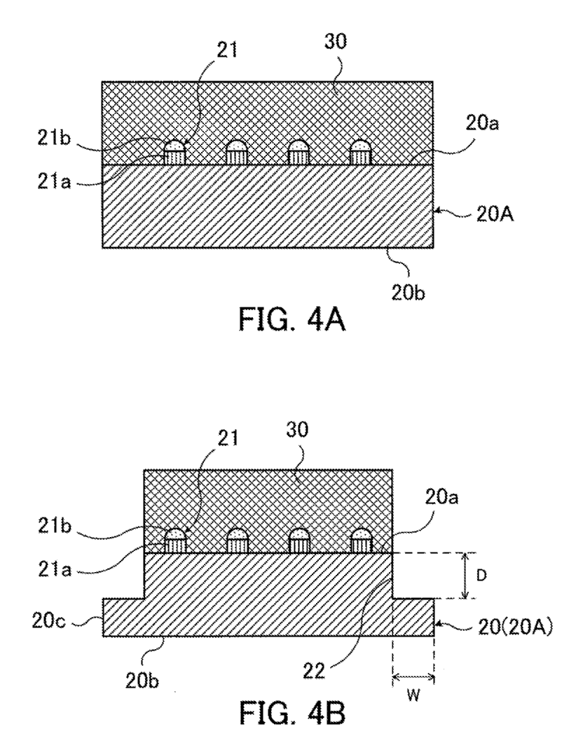

Hereinafter, an example of a method of forming the semiconductor device 1 will be described with reference to FIGS. 4A, 4B, 5, 6, 7A, 7B, and 7C.

FIGS. 4A, 4B, 5, 6, 7A, 7B, and 7C illustrate a method of forming a semiconductor device according to the first embodiment. In the following, an example of a method of forming a semiconductor device will be described step by step with reference to FIGS. 4A, 4B, 5, 6, 7A, 7B, and 7C.

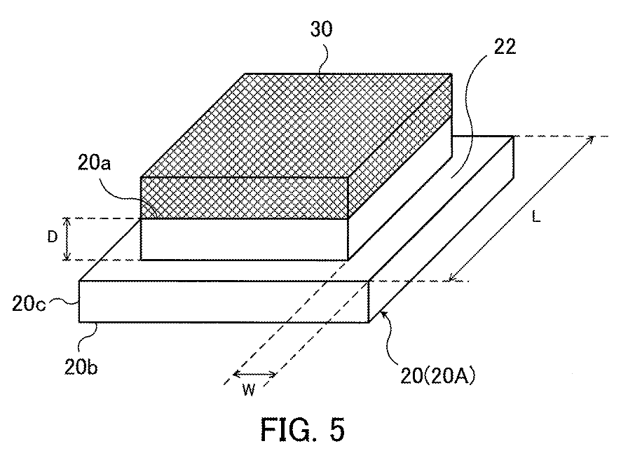

FIGS. 4A, 4B, and 5 illustrate an example of a process of forming a substrate having resin and a recess. More specifically, FIG. 4A is a schematic cross-sectional view of a main part illustrating an example of a resin forming process, and FIG. 4B is a schematic cross-sectional view of the main part illustrating an example of a recess forming process. FIG. 5 is a schematic perspective view of a main part illustrating an example of a substrate having resin and a recess.

As illustrated in FIG. 4A, a substrate 20A is prepared with a terminal 21 (for example, a plurality of terminals 21) disposed at a predetermined position. The substrate 20A is a substrate 20 before formation of a recess 22. Each terminal 21 includes a post 21a and a solder 21b at the distal end thereof. The terminals 21 are disposed at the positions corresponding to terminals 11 of a substrate 10 to which the substrate 20 is bonded. Resin such as NCP, NCF, and so on is disposed on a front surface 20a side of the prepared substrate 20A on which the terminals 21 are disposed. The resin 30 has a certain viscosity sufficient to be retained on the front surface 20a.

As illustrated in FIG. 4B, a recess 22 with a predetermined size (a width W, a depth D, and so on) is formed at an edge portion of the substrate 20A having the resin 30 on the front surface 20a. The recess 22 is formed by partially removing the resin 30 and the substrate 20A at the edge portion by using a dicer, laser, or the like. As illustrated in FIG. 5, for example, the recess 22 is provided at the entire peripheral edge portion of the substrate 20A (the substrate 20 formed from the substrate 20A).

In this manner, the substrate 20 having the resin 30 on the front surface 20a and having the recess 22 at the edge portion as illustrated in FIGS. 4B and 5 is obtained.

Note that in this example, the resin 30 is disposed on the substrate 20A first, and then the resin 30 and the substrate 20A at the edge portion are partially removed. However, the recess 22 may be formed in the substrate 20A first, and then the resin 30 is disposed in the area of the front surface 20a on the inner side of the recess 22.

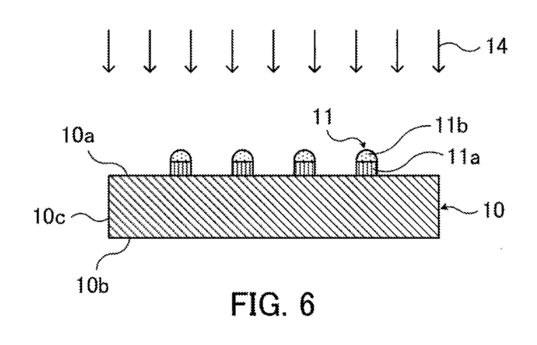

FIG. 6 illustrates an example of a process of forming a counterpart substrate. More specifically, FIG. 6 is a schematic cross-sectional view of a main part illustrating an example of a counterpart substrate forming process.

As illustrated in FIG. 6, as a substrate to be bonded to the substrate 20, a substrate 10 is prepared with a terminal 11 (for example, a plurality of terminals 11) disposed at a predetermined position. Each terminal 11 includes a post 11a and a solder 11b at the distal end thereof. The terminal 11 are disposed at the positions corresponding to the terminals 21 of the substrate 20.

As illustrated in FIG. 6, for example, an argon (Ar) plasma treatment 14 may be performed on a front surface 10a side of the substrate 10 on which the terminals 11 are disposed. The Ar plasma treatment 14 increases the wettability of the resin 30 with respect to the front surface 10a in the step of bonding described below. Accordingly, it is possible to increase the adhesion between the front surface 10a and the resin 30, and to suppress generation of voids between the front surface 10a and the resin 30.

As in the case of the substrate 10, an Ar plasma treatment may be performed on the front surface 20a of the substrate 20 before the resin 30 is disposed, so as to increase the adhesion between the front surface 20a and the resin 30 to be disposed thereon, and to suppress generation of voids between the front surface 20a and the resin 30. Further, an Ar plasma treatment may be performed on the recess 22 of the substrate 20 so as to increase the adhesion between the recess 22 and the resin 30, and to suppress generation of voids between the recess 22 and the resin 30.

The substrate 10 and the substrate 20 described above are used to form the semiconductor device 1.

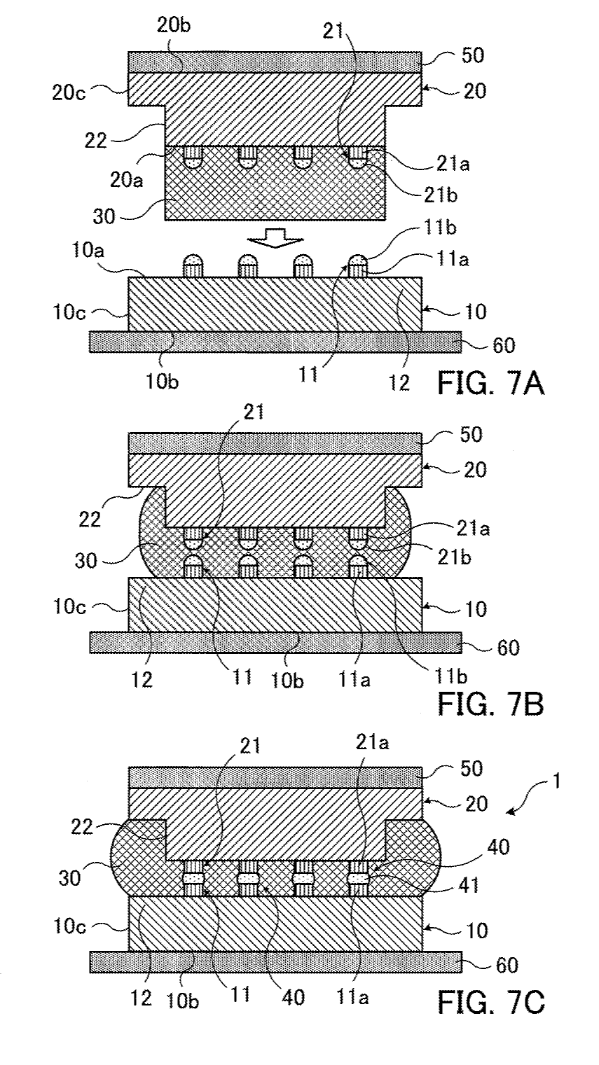

FIGS. 7A, 7B, and 7C illustrate an example of a process of forming a semiconductor device. More specifically, FIG. 7A is a schematic cross-sectional view illustrating an example of a main part before substrate bonding; FIG. 7B is a schematic cross-sectional view illustrating an example of the main part during substrate bonding; and FIG. 7C is a schematic cross-sectional view illustrating an example of the main part after substrate bonding.

As illustrated in FIG. 7A, the substrate 10 is sucked at the back surface 10b thereof and held on a suction stage (stage) 60. On the other hand, as illustrated in FIG. 7A, the substrate 20 having the resin 30 on the front surface 20a and having the recess 22 at the edge portion is sucked at the back surface 20b thereof and held on a bonding tool (head) 50. The substrate 20 sucked and held by the head 50 is disposed above the substrate 10 sucked and held on the stage 60 to face the substrate 10 in such a manner that the terminals 21 are aligned with the terminals 11.

As illustrated in FIG. 7B, the substrate 20 is pressed toward the substrate 10 with pressure applied thereto, while being heated by a heating mechanism provided in the head 50, for example. With the application of pressure, the substrate 10 and the substrate 20 are brought closer to each other, so that the gap therebetween is reduced. Accordingly, the resin 30 between the substrate 10 and the substrate 20 flows toward the sides (the edge portion 12 of the substrate 10 and the recess 22 of the substrate 20). As pressure is applied, the resin 30 reaches the edge portion 12 of the substrate 10, and part of the resin 30 flows into the recess 22 of the substrate 20.

With further application of pressure, the solders 21b of the terminals 21 of the substrate 20 come into contact with the corresponding solders 11b of the terminals 11 of the substrate 10, and are melted and integrated therewith by heat. Thus, solder bonding portions 41 illustrated in FIG. 7C are formed. As a result, the substrate 10 and the substrate 20 are bonded with connection portions 40 each including one post 11a, one solder bonding portion 41, and one post 21a, with a predetermined gap therebetween (with a height corresponding to the connection portions 40).

In the course of achieving a bonded state with the connection portions 40, the resin 30 between the substrate 10 and the substrate 20 flows toward the sides. However, as illustrated in FIGS. 7B and 7C, part of the resin 30 flowing toward the sides flows into the recess 22 of the substrate 20. Since the resin 30 flows into the recess 22, the speed of the resin 30 flowing toward the sides and the speed of the resin 30 that is pushed out to the outside of the substrate 10 (and the substrate 20) are reduced, so that the amount of the resin 30 that is pushed out to the outside of the substrate 10 is reduced.

Then, the resin 30 is cured by heat applied during formation of the connection portions 40, or by a curing process (application of heat, irradiation of light such as ultraviolet, or the like) after formation of the connection portions 40. As a result, the semiconductor device 1 is obtained in which the substrate 10 and the substrate 20 are electrically and mechanically connected through the connection portions 40, and in which the bonding strength between the substrate 10 and the substrate 20 is enhanced by the resin 30.

In the semiconductor device 1, the resin 30 that is caused to flow upon bonding flows into the recess 22 of the substrate 20, which reduces the speed and amount of the resin 30 that is pushed out to the outside of the substrate 10. Then, the resin 30 is cured. Thus, it is possible to prevent the resin 30 from flowing along the side surface 10c of the substrate 10 to the back surface 10b.

The capacity, that is, the size such as the width W, the depth D, the length L, and so on (FIGS. 4B and 5), of the recess 22 is set based on the volume of the resin 30 on the substrate 20A (FIG. 4B) and a gap between the substrate 10 and the substrate 20 after bonding with the connection portions 40 (FIG. 7C). When forming the substrate 20 illustrated in FIGS. 4B and 5, the recess 22 is formed to have a predetermined capacity and size by using a dicer, laser, or the like.

For example, assume that the planar size of the substrate 100 and the substrate 200 of FIG. 2 is 23 mm×23 mm; the gap between the substrate 100 and the substrate 200 after bonding is 30 μm; and the volume of the resin 300 per side that is pushed out upon bonding is 0.52 mm³. On the other hand, assume that the planar size of the substrate 10 and the substrate 20 of FIG. 7C is 23 mm×23 mm; the gap between the substrate 10 and the substrate 20 after bonding is 30 μm; a recess 22 (FIG. 5) with a width W of 0.1 mm, a depth D of 0.1 mm is disposed at the entire peripheral edge portion of the substrate 20. With the provision of this recess 22, the resin 30 having a certain viscosity is pushed out while maintaining the shape with a radius of curvature of about 0.05 mm, and its volume per side is 0.56 mm³. This volume is greater than the volume of the resin 300 (0.52 mm³) that is pushed out in the example of FIG. 2. Accordingly, with the provision of the recess having the size illustrated above, it is possible to prevent the resin 30 from flowing along the side surface 10c of the substrate 10 to the back surface 10b, thereby preventing contamination of the back surface 10b by resin.

With the method illustrated in FIGS. 4A, 4B, 5, 6, 7A, 7B, and 7C, the semiconductor device 1 of FIG. 3 is formed. In the semiconductor device 1, the recess 22 of the substrate 20 serves as a resin reservoir, so that the resin 30 that is caused to flow upon bonding to the substrate 10 flows into the recess 22. This reduces the speed and amount of the resin 30 that is pushed out to the outside of the substrate 10, and prevents the resin 30 from flowing along the side surface 10c of the substrate 10 to the back surface 10b. Even when there is a gap between the stage 60 sucking and holding the substrate 10 and the back surface 10b of the substrate 10 due to the structure of the back surface 10b (due to the structure of terminals, a passivation film, and so on), it is possible to prevent the resin 30 from flowing into the gap, thereby preventing contamination of the back surface 10b by resin.

As mentioned above, in the semiconductor device 1 described above, a semiconductor chip may be used as the substrate 20 having the recess 22, for example.

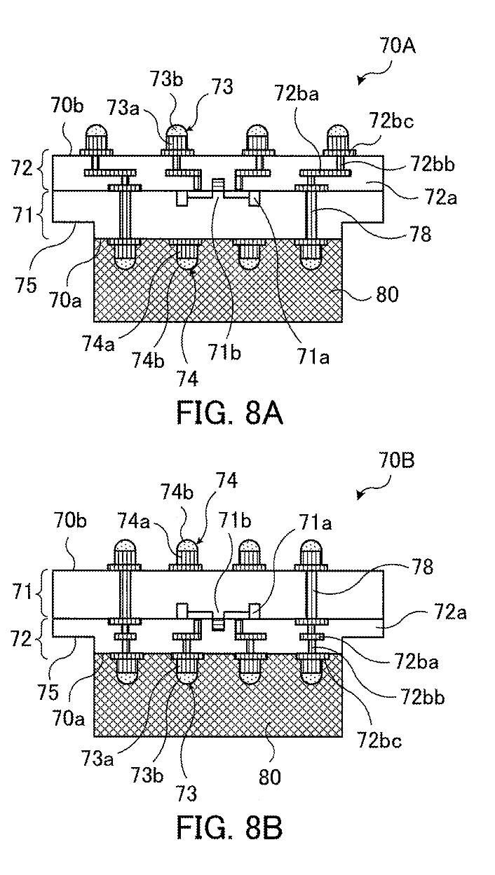

FIGS. 8A and 8B illustrate an example of the configuration of a semiconductor chip. More specifically, FIGS. 8A and 8B are schematic cross-sectional views of a main part, each illustrating an example of a semiconductor chip.

For example, a semiconductor chip 70A illustrated in FIG. 8A includes a semiconductor substrate 71 made of silicon (Si) or the like, and an interconnect layer 72 on the semiconductor substrate 71.

Circuit elements such as a transistor, a resistor, a capacitor, and so on are formed on the surface of the semiconductor substrate 71. In this example, a transistor 71b formed in an element region defined by an element isolation region 71a is illustrated as a circuit element formed on the semiconductor substrate 71.

The interconnect layer 72 includes conductive parts such as interconnect lines 72ba, vias 72bb, electrodes 72bc, and so on disposed inside an insulating portion 72a. The insulating portion 72a may be made of any of various organic or inorganic insulating materials. The conductive parts such as the interconnect lines 72ba, the vias 72bb, the electrodes 72bc, and so on may be made of any of various conductive materials such as Cu, aluminum (Al), and so on.

Terminals 73 are disposed on the electrodes 72bc of the interconnect layer 72. Each terminal 73 includes a post 73a protruding from a surface (back surface) 70b, and a solder 73b at the distal end thereof. The post 73a may be made of a material such as Cu, Ni, Au, and so on. As the solder 73b, solder containing Sn such as Sn—Ag solder and so on may be used. Circuit elements such as the transistor 71b formed on the semiconductor substrate 71 are electrically connected to the terminals 73 through the conductive parts such as the interconnect lines 72ba, the vias 72bb, the electrodes 72bc, and so on of the interconnect layer 72.

Further, the conductive parts of the interconnect layer 72 are electrically connected to terminals 74 on one surface (front surface) 70a, through TSVs 78 disposed in the semiconductor substrate 71. Each terminal 74 includes a post 74a protruding from the front surface 70a, and a solder 74b at the distal end thereof. The post 74a may be made of a material such as Cu, Ni, Au, and so on. As the solder 74b, solder containing Sn such as Sn—Ag solder and so on may be used. The terminal 74 is electrically connected to the conductive parts such as the interconnect line 72ba and so on of the interconnect layer 72, through the TSV 78.

In the semiconductor chip 70A illustrated in FIG. 8A, a recess 75 is provided in the semiconductor substrate 71, and resin 80 such as NCP, NCF, and so on is disposed in the area on the inner side of the recess 75.

As the substrate 20 described above, the semiconductor chip 70A of FIG. 8A may be used, for example. In the semiconductor chip 70A, when bonding the semiconductor substrate 71 side having the resin 80 and the recess 75 to a counterpart substrate (the substrate 10 described above) such as a semiconductor chip and the like, the recess 75 provided in the semiconductor substrate 71 serves as a resin reservoir for the resin 80 that is caused to flow by application of pressure for bonding. This prevents the resin 80 from flowing along the side surface of the counterpart substrate to the back surface thereof.

In a semiconductor chip 70B illustrated in FIG. 8B, a recess 75 is provided in an interconnect layer 72, and resin 80 such as NCP, NCF, and so on is disposed in the area on the inner side of the recess 75. In the semiconductor chip 70B, terminals 73 connected to conductive parts of the interconnect layer 72 are disposed on a surface (front surface) 70a side on which the resin 80 is disposed, while terminals 74 connected to TSVs 78 in a semiconductor substrate 71 are disposed at a surface (back surface) 70b side opposite thereto. The semiconductor chip 70B of FIG. 8B differs from the semiconductor chip 70A of FIG. 8A in this regard. In this manner, the recess 75 may be provided in the interconnect layer 72 other than the semiconductor substrate 71.

As the substrate 20 described above, the semiconductor chip 70B of FIG. 8B may be used, for example. In the semiconductor chip 70B, when bonding the interconnect layer 72 side having the resin 80 and the recess 75 to a counterpart substrate (the substrate 10 described above) such as a semiconductor chip and the like, the recess 75 provided in the interconnect layer 72 serves as a resin reservoir for the resin 80 that is caused to flow by application of pressure for bonding. This makes it possible to prevent the resin 80 from flowing along the side surface of the counterpart substrate to the back surface thereof.

Note that as another example of the semiconductor chip 70A of FIG. 8A, the recess 75 may be formed to extend through the semiconductor substrate 71 to the interconnect layer 72. Further, as another example of the semiconductor chip 70B of FIG. 8B, the recess 75 may be formed to extend through the interconnect layer 72 to the semiconductor substrate 71.

The semiconductor chip 70A and the semiconductor chip 70B may be formed by the following method, for example.

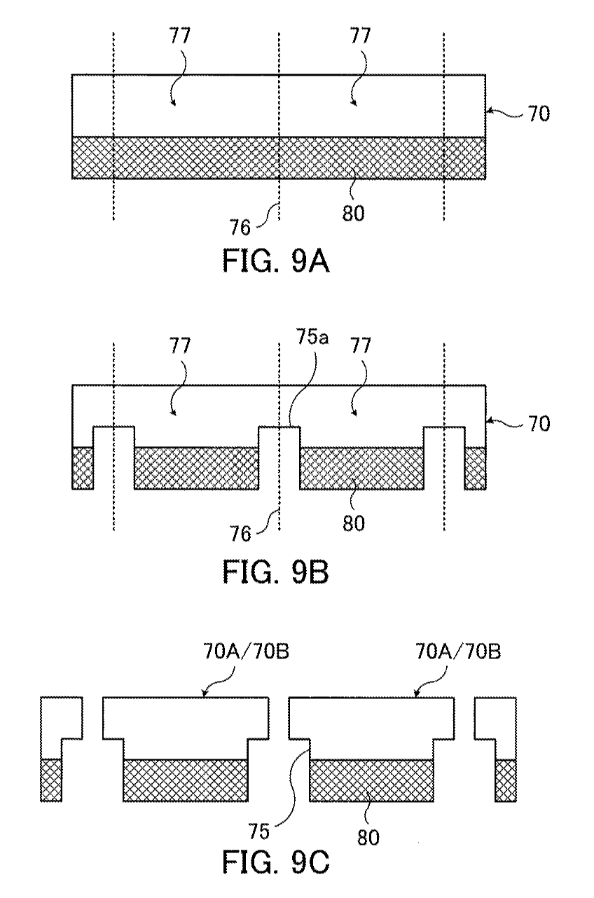

FIGS. 9A to 9C illustrate an example of a method of forming a semiconductor chip. More specifically, FIG. 9A is a schematic cross-sectional view of a main part illustrating an example of a resin forming process; FIG. 9B is a schematic cross-sectional view of the main part illustrating an example of a recess forming process; and FIG. 9C is a schematic cross-sectional view of the main part illustrating a dicing process.

A wafer 70 illustrated in FIG. 9A is prepared, and resin 80 is disposed on one surface thereof, for example. The wafer 70 includes a plurality of dicing lines 76. Each region enclosed by the dicing lines 76 is a region (semiconductor chip formation region) 77 where a semiconductor chip 70A or a semiconductor chip 70B before dicing is formed. Resin 80 is disposed on a semiconductor substrate of the wafer 70 on which circuit elements such as a transistor and so on are formed, or on an interconnect layer formed on the semiconductor substrate. Note that the internal structure of the wafer 70 and terminals of the wafer 70 are omitted in FIGS. 9A to 9C.

Then, as illustrated in FIG. 9B, bottomed (half-cut structure) recesses 75a of a predetermined size are formed in the wafer 70 with the resin 80 thereon, along the dicing lines 76, by using a dicer, laser, or the like. For example, each recess 75a is formed such that the dicing line 76 passes through the center of the recess 75a in cross section.

After that, dicing is performed to cut the wafer (and the resin 80) along the dicing lines 76, by using a dicer. Thus, as illustrated in FIG. 9C, diced semiconductor chips 70A (FIG. 8A) or semiconductor chips 70B (FIG. 8B) are obtained. Each recess 75a formed in the process of FIG. 9B is cut into halves by dicing in the process of FIG. 9C, so that a recess 75 is formed at the edge portion of each of the obtained semiconductor chips 70A or semiconductor chips 70B.

The semiconductor chip 70A or the semiconductor chip 70B obtained in this manner is bonded to a predetermined counterpart substrate with resin 80.

Note that, prior to the dicing, the wafer 70 provided with the resin 80 and the recesses 75 as illustrated in FIGS. 9A and 9B may be bonded to another wafer (not diced). After bonding to the other wafer, dicing along the dicing lines 76 may be performed to obtain structures in which the semiconductor chips 70A or the semiconductor chips 70B formed by dicing the wafer 70 and semiconductor chips formed by dicing the other wafer are respectively bonded with the resin 80.

Further, a circuit board such as an interposer may be used as the substrate 20.

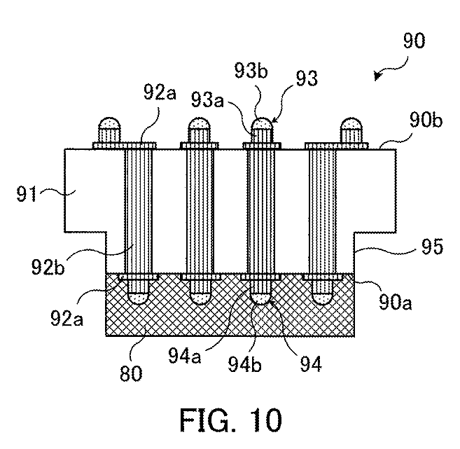

FIG. 10 illustrates an example of the configuration of an interposer. More specifically, FIG. 10 is a schematic cross-sectional view of a main part illustrating an example of an interposer.

An interposer 90 illustrated in FIG. 10 includes a base 91, and conductive parts such as interconnect lines 92a, vias 92b, and so on. The base 91 may be made of materials such as Si, glass, and so on. The conductive parts may be made of any of various conductive materials such as Cu and so on.

Terminals 93 are disposed on some portions (electrodes) of the interconnect lines 92a on one surface (back surface) 90b of the interposer 90. Each terminal 93 includes a post 93a protruding from the back surface 90b, and a solder 93b disposed at the distal end thereof. Terminals 94 are disposed on some portions (electrodes) of the interconnect lines 92a on another surface (front surface) 90a of the interposer 90. Each terminal 94 includes a post 94a protruding from the front surface 90a, and a solder 94b disposed at the distal end thereof. The post 93a and the post 94a may be made of a material such as Cu, Ni, Au, and so on. As the solder 93b and the solder 94b, solder containing Sn such as Sn—Ag solder and so on may be used. The interconnect lines 92a on the front surface 90a and the interconnect lines 92a on the back surface 90b of the interposer 90 are electrically connected through the vias 92b.

A recess 95 is provided on, for example, the front surface 90a side of the interposer 90, and resin 80 is disposed in the area on the inner side of the recess 95.

For example, the interposer 90 of FIG. 10 may be used as the substrate 20 described above. In the interposer 90, when bonding the surface side having the resin 80 and the recess 95 to a counterpart substrate (the substrate 10 described above) such as a semiconductor chip and the like, the recess 95 serves as a resin reservoir for the resin 80 that is caused to flow by application of pressure for bonding. This makes it possible to prevent the resin 80 from flowing along the side surface of the counterpart substrate to the back surface thereof.

The recess 22 provided in the substrate 20 will be further described.

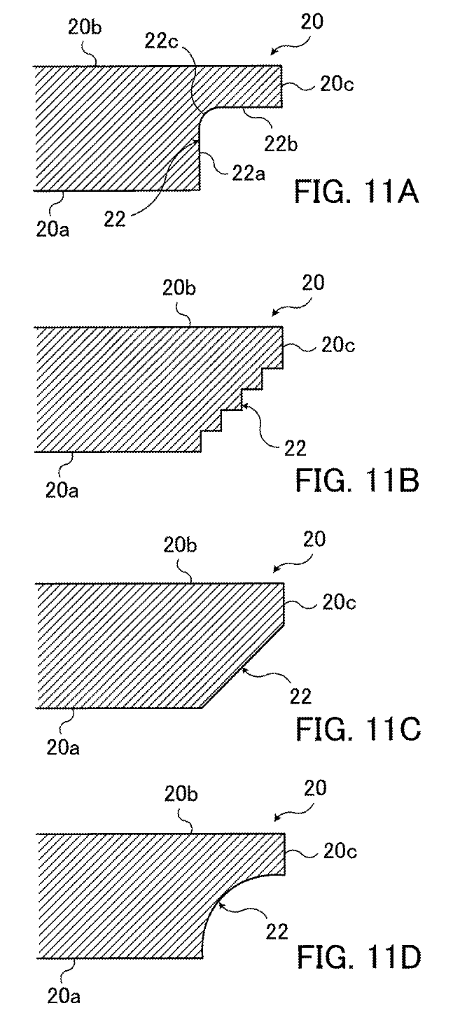

FIGS. 11A to 11D illustrate the shape of a recess. More specifically, FIGS. 11A to 11D are schematic cross-sectional views of a main part, each illustrating an example of a substrate having a recess.

As illustrated in FIG. 11A, the recess 22 of the substrate 20 may be formed such that a corner 22c where an inner wall surface 22a and a bottom surface 22b meet has a rounded shape in cross section. For example, the corner 22c may have a curved surface with a curvature radius of 0.01 mm or greater. The recess 22 having the corner 22c illustrated in FIG. 11A may be formed by performing cutting from the front surface 20a side, using a dicer, laser, or the like, for example. In this case, the curvature radius of the corner 22c may be adjusted in accordance with the shape of the peripheral cutting edge of the dicer to be used or the laser irradiation conditions.

As illustrated in FIGS. 7A to 7C, when bonding the substrate 20 and the substrate 10, the resin 30 caused to flow by application of pressure flows into the recess 22. In the case where the corner 22c of the recess 22 has a curved surface as illustrated in FIG. 11A, the resin 30 flowing into the recess 22 easily tightly adheres to the inner wall surface 22a, the corner 22c, and the bottom surface 22b of the recess 22. Compared to a recess in which the corner does not have a curved surface, the resin 30 more easily tightly adheres to the corner 22c having a curved surface, in addition to the inner wall surface 22a and the bottom surface 22b. Thus, it is possible to suppress generation of voids between the recess 22 and the resin 30 flowing thereinto.

In the case where there are voids between the recess 22 of the substrate 20 and the resin 30, when the temperature of a structure in which the substrate 10 and the substrate 20 are bonded increases, gas in the voids expands, which may result in separation of the resin 30 from the substrate 20. The separation of the resin 30 from the substrate 20 may reduce the bonding strength between the substrate 10 and the substrate 20 bonded with the resin 30, and reduce the reliability and quality of the bonded structure including the substrate 10 and the substrate 20, and the semiconductor device 1 including the bonded structure. Accordingly, it is preferable that there is no void between the recess 22 of the substrate 20 and the resin 30.

Further, as illustrated in FIG. 11B, the recess 22 of the substrate 20 may be formed such that the depth increases stepwise toward the side surface 20c of the substrate 20 in cross section. The stepped recess 22 of FIG. 11B may be formed by performing cutting from the front surface 20a side at different depth, using a dicer having peripheral cutting edges of different widths or the same width, for example.

Since the recess 22 has a stepped shape whose depth changes stepwise, it is possible to increase the contact area between the inner surface of the recess 22 and the resin 30 flowing into the recess 22 upon bonding the substrate 20 and the substrate 10. This increases the adhesion strength between the substrate 20 and the resin 30, and further enhances the bonding strength between the substrate 20 and the substrate 10 that are bonded with the resin 30.

Note that, in the stepped recess 22 illustrated in FIG. 11B, the corner of each step where an inner wall surface and a bottom surface meet may have a curved surface (rounded shape) in accordance with the example of FIG. 11A.

Further, the recess 22 of the substrate 20 may have a tapered shape whose depth increases toward the side surface 20c of the substrate 20 in cross section as illustrated in FIG. 11C, or may have a curved shape whose depth increases toward the side surface 20c of the substrate 20 in cross section as illustrated in FIG. 11D. The tapered recess 22 of FIG. 11C may be formed by performing cutting from the front surface 20a side, using a dicer having a peripheral cutting edge with a V shape. The curved recess 22 of FIG. 11D may be formed by performing cutting from the front surface 20a side, using a dicer having a peripheral cutting edge with a U shape.

In the case where the recess 22 has a shape whose depth changes continuously as illustrated in FIGS. 11C and 11D, the resin 30 flowing into the recess 22 upon bonding the substrate 20 and the substrate 10 easily tightly adheres to the inner surface of the recess 22. Thus, it is possible to suppress generation of voids between the resin 30 and the recess 22.

The recess 22 of the substrate 20 may have various shapes in accordance with examples of shapes illustrated in FIG. 11A to 11D.

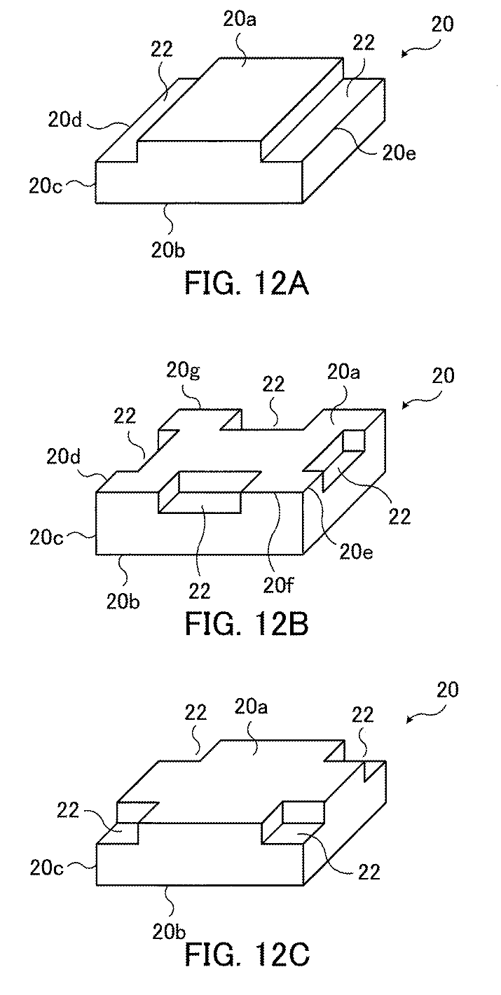

FIGS. 12A to 12C illustrate the arrangement of a recess. More specifically, FIGS. 12A to 12C are schematic perspective views of a main part, each illustrating an example of a substrate having a recess.

In the example illustrated in FIG. 5, the recess is disposed at the entire peripheral edge portion of the substrate 20. Since the recess 22 is disposed at the entire peripheral edge portion of the substrate 20, a large capacity resin reservoir extending along the entire periphery of the substrate 20 is provided, thereby preventing the resin 30 from flowing to the back surface 10b of the substrate 10.

Alternatively, the recess 22 of the substrate 20 may be provided at a part of the peripheral edge portion of the substrate 20.

For example, as illustrated in FIG. 12A, the recess 22 may be provided at the edge portion along at least one side of the substrate 20. In the example illustrated in FIG. 12A, the recess 22 is provided at each of the edge portions along two opposing sides 20d and 20e. By arranging the recesses 22 as illustrated in FIG. 12A, it is possible to reduce man-hours and cost needed to form the recess 22 compared to the case where the recess 22 is provided at the entire peripheral edge portion.

Further, as illustrated in FIG. 12B, the recess 22 may be provided at a part of the edge portion along at least one side of the substrate 20. In the example illustrated in FIG. 12B, the recess 22 is provided at the center of each of the edge portions along the four sides 20d, 20e, 20f, and 20g. For example, in the case of bonding a substrate 20 without a recess 22 and the substrate 10, the resin 30 may be more easily pushed out to the outside of the edge portions along the sides 20d, 20e, 20f, and 20g than to the outside of the edge portions at the four corners, with the application of pressure. In this case, by arranging the recesses 22 as illustrated in FIG. 12B, it is possible to prevent the resin 30 from being pushed out to the outside of the edge portions along the sides 20d, 20e, 20f, and 20g. Note that the number of recesses 22 provided at the edge portions along the sides 20d, 20e, 20f, and 20g is not limited to those illustrated in FIGS. 12A and 12B.

Further, as illustrated in FIG. 12C, the recess 22 may be provided at the edge portion at least at one corner of the substrate 20. In the example illustrated in FIG. 12C, the recess 22 is provided at each of the edge portions at the four corners. For example, in the semiconductor device 1 in which the substrate 10 and the substrate 20 are bonded with the resin 30, deformation and stress may occur more easily at the corners than at the center. In this case, by arranging the recesses 22 in the substrate 20 as illustrated in FIG. 12C, a relatively large amount of resin 30 is concentrated at the corners of the semiconductor device 1. Thus, it is possible to increase the adhesion strength provided by the resin 30, and to reduce the stress.

In the substrate 20, the recesses 22 may be arranged in various manners, in accordance with the examples of arrangements illustrated in FIGS. 12A to 12C.

As described above, in the semiconductor device 1 according to the first embodiment, the recess 22 is provided in the substrate 20. Accordingly, when bonding the substrate 20 to the substrate 10 with the resin 30, the resin 30 caused to flow by application of pressure flows into the recess 22. Thus, it is possible to prevent the resin 30 of an amount greater than a certain amount from being pushed out to the outside of the substrate 10. Consequently, it is possible to prevent the resin 30 from flowing along the side surface 10c of the substrate 10 to the back surface 10b, thereby preventing contamination of the back surface 10b by resin.

Accordingly, even when terminals for electrically connecting another substrate are provided on the back surface 10b of the substrate 10, it is possible to prevent the resin 30 from flowing to the back surface 10b and covering the terminals, and to prevent a poor electrical connection between the terminals and the other substrate. Further, there is no need to add a process of removing the resin 30 that has flowed to the back surface 10b in order to prevent a poor connection, before bonding to the other substrate. Further, in the case where the back surface 10b of the substrate 10 serves as an exterior surface, it is possible to provide a semiconductor device with a good appearance by preventing contamination of the back surface 10b by resin.

According to the first embodiment, it is possible to provide a high-quality semiconductor device 1, and to manufacture such a high-quality semiconductor device 1 while minimizing a reduction in manufacturing efficiency due to increased man-hours, and minimizing an increase in manufacturing cost.

In the following, a second embodiment will be described.

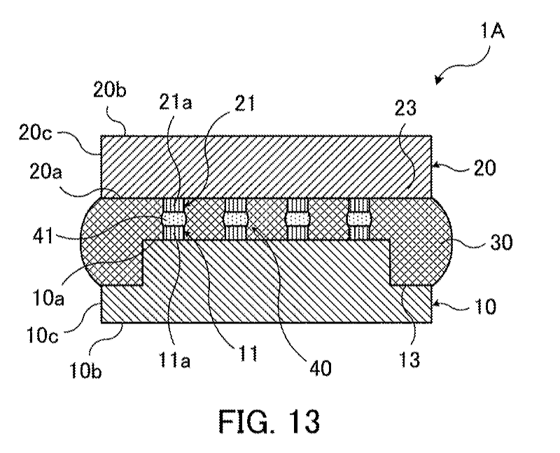

FIG. 13 illustrates an example of a semiconductor device according to the second embodiment. More specifically, FIG. 13 is a schematic cross-sectional view of a main part illustrating an example of a semiconductor device according to the second embodiment.

A semiconductor device 1A illustrated in FIG. 13 differs from the semiconductor device 1 of the first embodiment (FIG. 3) in that a recess is not provided in an upper substrate 20 but a bottomed recess 13 (cutout) serving as a resin reservoir is provided in a lower substrate 10 to be bonded to the substrate 20.

The recess 13 of the substrate 10 is provided at the position corresponding to an edge portion 23 of the substrate 20, in a front surface 10a facing the substrate 20. The edge portion 23 of the substrate 20 is, for example, a portion on the outer side of the area where the terminals 21 are disposed. In the substrate 10, the recess 13 is provided at the position corresponding to the edge portion 23 of the substrate 20. The recess 13 has a shape that extends to a side surface 10c of the substrate 10, for example.

The substrate 10 has a planar size equal to or smaller than that of the substrate 20, for example. In this example, the substrate 10 and the substrate 20 have the same planar size.

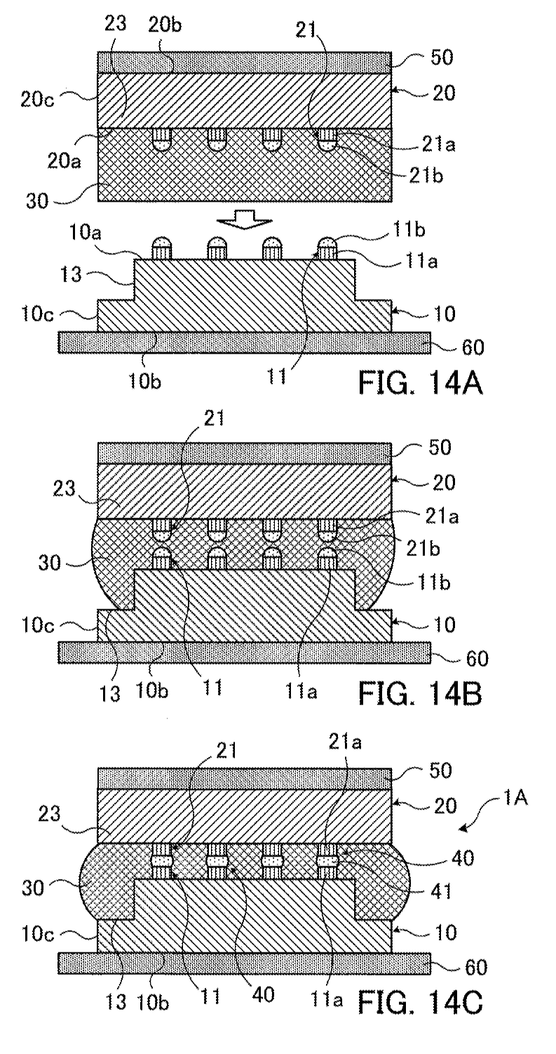

FIGS. 14A to 14C illustrate an example of a process of forming a semiconductor device according to the second embodiment. More specifically, FIG. 14A is a schematic cross-sectional view illustrating an example of a main part before substrate bonding; FIG. 14B is a schematic cross-sectional view illustrating an example of the main part during substrate bonding; and FIG. 14C is a schematic cross-sectional view illustrating an example of the main part after substrate bonding.

As illustrated in FIG. 14A, the substrate 10 having the recess 13 at the edge portion on the front surface 10a side is sucked at the back surface 10b thereof and held on the stage 60. As illustrated in FIG. 14A, the substrate 20 having the resin 30 on the front surface 20a is sucked at the back surface 20b thereof and held by the head 50. The substrate 20 sucked and held by the head 50 is disposed above the substrate 10 sucked and held on the stage 60 to face the substrate 10 in such a manner that the terminals 21 are aligned with the terminals 11.

As illustrated in FIG. 14B, the substrate 20 is pressed toward the substrate 10 with pressure applied thereto, while being heated by a heating mechanism provided in the head 50, for example. With the application of pressure, the substrate 10 and the substrate 20 are brought closer to each other. Thus, the resin 30 between the substrate 10 and the substrate 20 flows toward the sides (the recess 13 of the substrate 10 and the edge portion 23 of the substrate 20), and part of the resin 30 flows into the recess 13 of the substrate 10.

With further application of pressure, the solders 21b of the terminals 21 of the substrate 20 come into contact with the corresponding solders 11b of the terminals 11 of the substrate 10, and are melted and integrated therewith by heat. Thus, solder bonding portions 41 illustrated in FIG. 14C are formed. As a result, the substrate 10 and the substrate 20 are bonded with connection portions 40 each including one post 11a, one solder bonding portion 41, and one post 21a, with a predetermined gap therebetween (with a height corresponding to the connection portions 40).

In the course of achieving a bonded state with the connection portions 40, the resin 30 between the substrate 10 and the substrate 20 flows toward the sides. However, part of the resin 30 flows into the recess 13. This reduces the speed of the resin 30 flowing toward the sides and the speed of the resin 30 that is pushed out to the outside of the substrate 10, and hence reduces the amount of the resin 30 that is pushed out to the outside of the substrate 10.

Then, the resin 30 is cured by heat applied during formation of the connection portions 40, or by a curing process (application of heat, irradiation of light such as ultraviolet, or the like) after formation of the connection portions 40. As a result, the semiconductor device 1A is obtained in which the substrate 10 and the substrate 20 are electrically and mechanically connected through the connection portions 40, and in which the bonding strength between the substrate 10 and the substrate 20 is enhanced by the resin 30.

In the semiconductor device 1A, the resin 30 that is caused to flow upon bonding flows into the recess 13 of the substrate 10, which reduces the speed and amount of the resin 30 that is pushed out to the outside of the substrate 10. Then, the resin 30 is cured. Thus, it is possible to prevent the resin 30 from flowing along the side surface 10c of the substrate 10 to the back surface 10b.

In this manner, even in the case where the recess 13 is provided in the lower substrate 10, it is possible to prevent contamination of the back surface 10b of the substrate 10 by resin.

The recess 13 of the substrate 10 used in the semiconductor device 1A may be formed by partially removing an edge portion of the substrate 10, which has the terminals 11 each including the post 11a with a solder at the distal end thereof, by using a dicer, laser, or the like, in accordance with the example of FIG. 4B and so on, for example. Note that as illustrated in FIG. 14A, in the case where the resin 30 is provided on the substrate 20 for bonding, there is no need to provide the resin 30 on the substrate 10.

As the substrate 10 of the semiconductor device 1A, the semiconductor chip 70A of FIG. 8A or 9C and the semiconductor chip 70B of FIG. 8B or 9C may be used, for example. Further, as the substrate 10 of the semiconductor device 1A, the wafer 70 of FIG. 9A, the interposer 90 of FIG. 10, or the like may be used. Note that as illustrated in FIG. 14A, in the case where the resin 30 is provided on the substrate 20 for bonding, there is no need to provide the resin 80 on the semiconductor chip 70A or 70B, the wafer 70, the interposer 90, or the like, used as the substrate 10. Further, there is no need to provide protruding terminals such as posts on a surface (stage-side surface) opposite to a surface with the recess 75, in the semiconductor chip 70A or 70B, the wafer 70, the interposer 90, or the like, used as the substrate 10.

Further, as in the case of FIG. 11A, the recess 13 of the substrate 10 used in the semiconductor device 1A may be formed such that a corner where an inner wall surface and a bottom surface meet has a curved surface (rounded shape) in cross section. Thus, it is possible to suppress generation of voids between the recess 13 and the resin 30 flowing thereinto upon bonding the substrate 10 and the substrate 20. Further, as in the case of FIG. 11B, the recess 13 may have a stepped shape in cross section so as to increase the contact area between the recess 13 and the resin 30 flowing thereinto, and thereby enhance the bonding strength between the substrate 10 and the substrate 20. Further, as in the case of FIGS. 11C and 11D, the recess 13 may have a tapered shape or a curved shape in cross section so as to suppress generation of voids between the recess 13 and the resin 30 flowing thereinto.

Further, as in the case of FIG. 5, for example, the recess 13 of the substrate 10 used in the semiconductor device 1A may be disposed at the entire peripheral edge portion of the substrate 10. Further, the recess 13 may be provided at a part of the peripheral edge portion of the substrate 10. For example, as in the case of FIG. 12A, the recess 13 may be provided at the edge portion along a given side of the substrate 10 so as to reduce man-hours and cost needed to form the recess 13. Further, as in the case of FIG. 12B, the recess 13 may be provided at a part of the edge portion along a given side of the substrate 10 so as to reduce the amount of the resin 30 that is pushed out from that side. Further, as in the case of FIG. 12C, the recess 13 may be provided at the edge portion at a given corner of the substrate 10 so as to concentrate the resin 30 at that corner, and thereby enhance the bonding strength between the substrate 10 and the substrate 20.

According to the second embodiment, the recess is provided in the lower substrate 10, thereby preventing contamination of the back surface 10b of the substrate 10 by resin. Thus, it is possible to provide a high-quality semiconductor device 1A.

In the following, a third embodiment will be described.

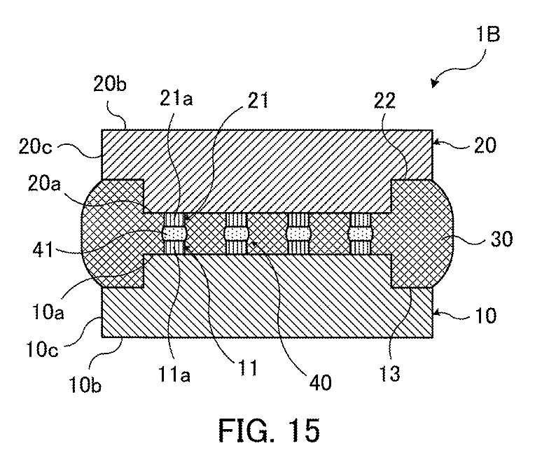

FIG. 15 illustrates an example of a semiconductor device according to the third embodiment. More specifically, FIG. 15 is a schematic cross-sectional view of a main part illustrating an example of a semiconductor device according to the third embodiment.

A semiconductor device 1B illustrated in FIG. 15 differs from the semiconductor device 1 of the first embodiment (FIG. 3) and the semiconductor device 1A of the second embodiment (FIG. 13) in that a substrate 10 having a recess 13 and a substrate 20 having a recess 22 are bonded with resin 30.

The substrate 10 having the recess 13 may be formed in the manner described in the second embodiment. The substrate 20 having the recess 22 may be formed in the manner described in the first embodiment.

The substrate 10 has a planar size equal to or smaller than that of the substrate 20, for example. In this example, the substrate 10 and the substrate 20 have the same planar size.

When bonding the substrate 10 having the recess 13 and the substrate 20 having the recess 22, part of the resin 30 that is caused to flow by application of pressure for bonding flows into the recess 13 and the recess 22. This reduces the speed of the flowing resin 30 and the speed of the resin 30 that is pushed out to the outside of the substrate 10, and hence reduces the amount of the resin 30 that is pushed out to the outside of the substrate 10. Then, connection portions 40 are formed, and the resin 30 is cured. Thus, the semiconductor device 1B is obtained.

Since the recess 13 and the recess 22 are provided in the substrate 10 and the substrate 20, respectively, it is possible to reduce the speed and amount of the resin 30 that is pushed out to the outside, and prevent the resin 30 from flowing along the side surface 10c of the substrate 10 to the back surface 10b, thereby preventing contamination of the back surface 10b by resin.

In the substrate 10 of the semiconductor device 1B, the recess 13 may be shallower compared to the case where a counterpart substrate is a substrate 20 not having a recess as described in the second embodiment, for example. Similarly, in the substrate 20 of the semiconductor device 1B, the recess 22 may be shallower compared to the case where a counterpart substrate is a substrate 10 not having a recess as described in the first embodiment, for example.

That is, the sizes (capacities) of the recess 13 and the recess 22 are set based on the amount of the resin 30 that is pushed out to the outside of the substrate 10 in the case where the recess 13 and the recess 22 are not provided. Therefore, in the case where both the recess 13 and the recess 22 are provided as in the semiconductor device 1B, their sizes may be reduced as compared to the case where only the recess 13 or only the recess 22 is provided. Accordingly, the shallow recess 13 and the shallow recess 22 described above may be formed.

Further, if it does not suffice to provide only the recess 13 or only the recess 22 to accommodate the amount of the resin 30 that is pushed out to the outside of the substrate 10 in the case where the recess 13 and the recess 22 are not provided, both the recess 13 and the recess 22 may be provided as in the semiconductor device 1B. For example, if it is not possible to form a recess 22 with a sufficient depth to accommodate the amount of such resin 30 due to the internal structure of the substrate 20, or if it is not possible to form a recess 13 with a sufficient depth due to the internal structure of the substrate 10, both the recess 13 and the recess 22 may be provided.

Further, even when it suffices to provide only the recess 13 or only the recess 22 to accommodate the amount of the resin 30 that is pushed out to the outside of the substrate 10 in the case where the recess 13 and the recess 22 are not provided, both the recess 13 and the recess 22 may be provided to ensure a sufficient capacity.

Note that in the case where the recess 13 and the recess 22 are provided in the substrate 10 and the substrate 20, respectively, the recess 13 and the recess 22 do not have to be disposed at corresponding positions.

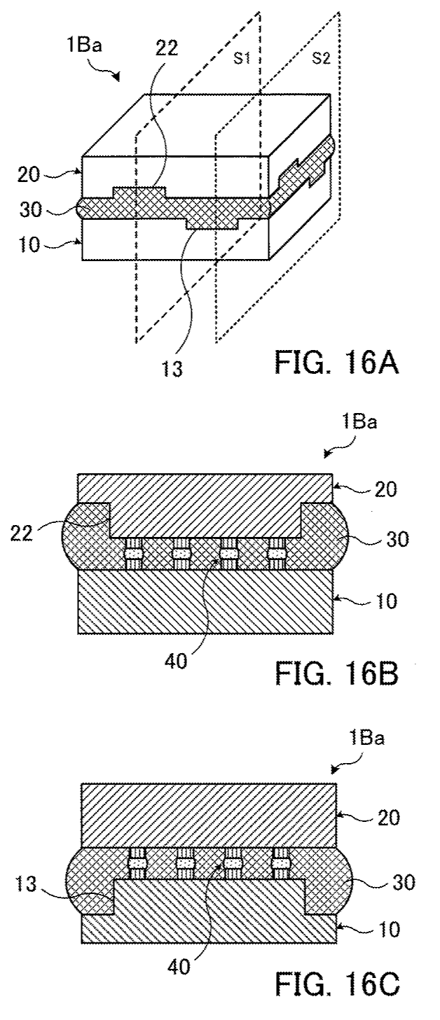

FIGS. 16A to 16C illustrate another example of a semiconductor device according to the third embodiment. More specifically, FIG. 16A is a schematic cross-sectional view of a main part illustrating another example of a semiconductor device according to the third embodiment; FIG. 16B is a schematic cross-sectional view taken along a plane S1 of FIG. 16A; and FIG. 16C is a schematic cross-sectional view taken along a plane S2 of FIG. 16A.

As illustrated in FIGS. 16A to 16C, a semiconductor device 1Ba has a structure in which a substrate 10 having a recess 13 and a substrate 20 having a recess 22 are bonded with resin 30, and the recess 13 and the recess 22 are disposed at non-corresponding positions.

As long as the recess 13 and the recess 22 together have a capacity equal to or greater than a predetermined capacity, that is, a sufficient capacity to accommodate the amount of the resin 30 that is pushed out to the outside of the substrate 10 in the case where the recess 13 and the recess 22 are not provided, the recess 13 and the recess 22 may be provided at non-corresponding positions. Even when the recess 13 and the recess 22 have such a non-corresponding positional relationship, it is possible to prevent the resin 30 from flowing along the side surface 10c of the substrate 10 to the back surface 10b upon bonding the substrate 10 and the substrate 20, thereby preventing contamination of the back surface 10b by resin.

According to the third embodiment, the recess 13 and the recess 22 are provided in the lower substrate 10 and the upper substrate 20, respectively, thereby preventing contamination of the back surface 10b of the substrate 10 by resin. Thus, it is possible to provide high-quality semiconductor device 1B and semiconductor device 1Ba.

In the following, a fourth embodiment will be described.

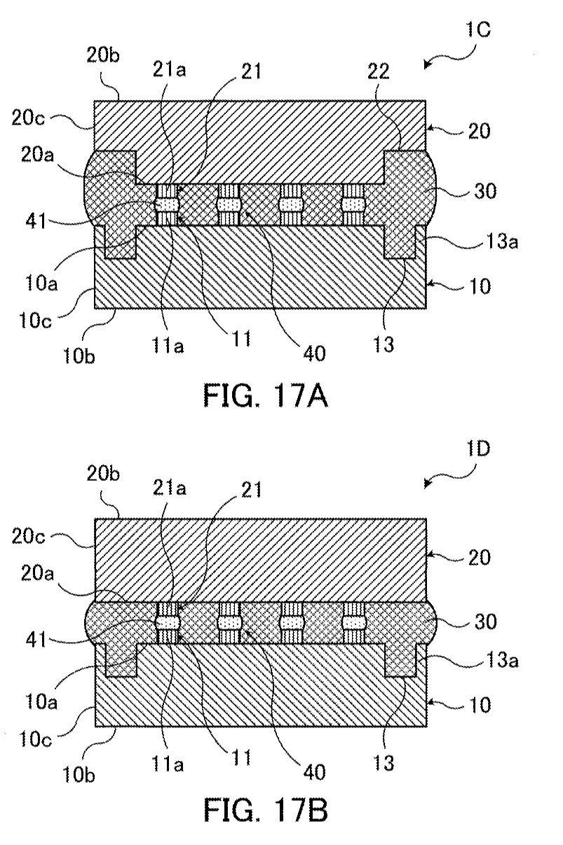

FIGS. 17A and 17B illustrate an example of a semiconductor device according to the fourth embodiment. More specifically, FIGS. 17A and 17B are schematic cross-sectional views of a main part, each illustrating an example of a semiconductor device according to the fourth embodiment.

A semiconductor device 1C illustrated in FIG. 17A differs from the semiconductor device 1 (FIG. 3) of the first embodiment in that a recess 13 is provided on the inner side of a side surface 10c, at an edge portion of a lower substrate 10 that is bonded to an upper substrate 20 having a recess 22.

Further, a semiconductor device 1D illustrated in FIG. 17B differs from the semiconductor device 1A (FIG. 13) of the second embodiment in that a recess 13 is provided on the inner side of a side surface 10c, at an edge portion of a lower substrate 10 that is bonded to an upper substrate 20 not having a recess.

In each of the semiconductor device 1C and the semiconductor device 1D, the substrate 10 has a planar size equal to or smaller than that of the substrate 20, for example. In this example, the substrate 10 and the substrate 20 have the same planar size.

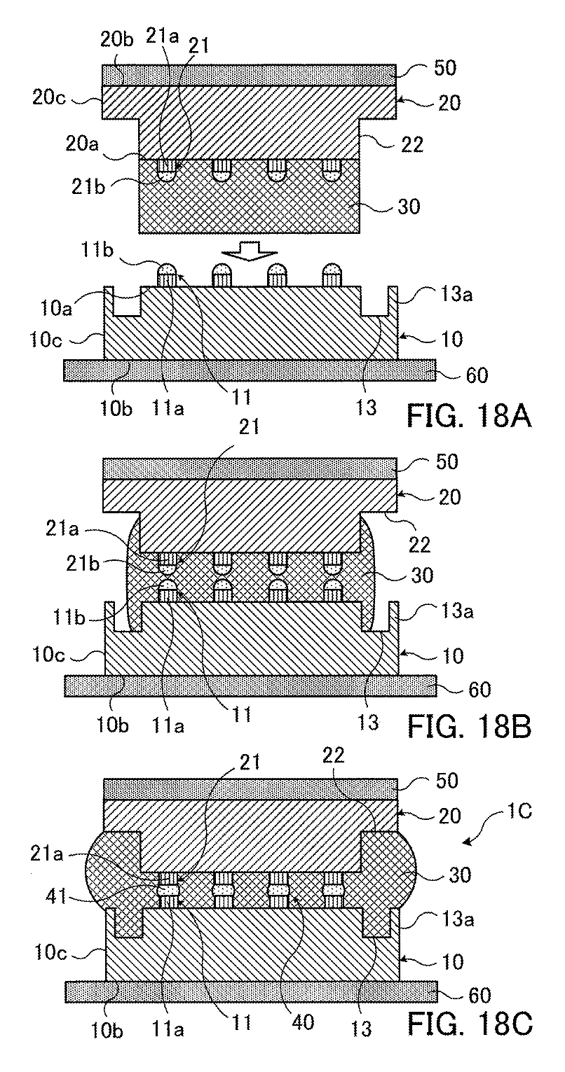

FIGS. 18A to 18C illustrate an example of a process of forming a semiconductor device according to the fourth embodiment. More specifically, FIG. 18A is a schematic cross-sectional view illustrating an example of a main part before substrate bonding; FIG. 18B is a schematic cross-sectional view illustrating an example of the main part during substrate bonding; and FIG. 18C is a schematic cross-sectional view illustrating an example of the main part after substrate bonding.

In FIGS. 18A to 18C, a process of forming the semiconductor device 1C of FIG. 17A is illustrated by way of example. As illustrated in FIG. 18A, when forming the semiconductor device 1C, the substrate 20 sucked and held by the head 50 is disposed above the substrate 10 sucked and held on the stage 60 to face the substrate 10 in such a manner that the terminals 21 are aligned with the terminals 11. The substrate 20 is pressed toward the substrate 10 with pressure applied thereto, while being heated by a heating mechanism provided in the head 50, for example. In the process of applying heat and pressure, as illustrated in FIGS. 18B and 18C, the substrate 10 and the substrate 20 are brought closer to each other, causing the resin 30 therebetween to flow. Thus, as illustrated in FIG. 18C, connection portions 40 are formed, and the resin 30 is cured, so that the semiconductor device 1C is obtained. Note that the semiconductor device 1D of FIG. 17B may be obtained with the same procedure.

In the substrate 10, the recess 13 is provided on the inner side of the side surface 10c thereof. Therefore, as illustrated in FIGS. 18B and 18C, a wall 13a of the recess 13 on the side surface 10c side servers as a dam for holding back the resin 30 that is caused to flow upon bonding to the upper substrate 20 (dam effects). Thus, it is possible to further inhibit the resin 30 from reaching the side surface 10c and to prevent the resin 30 from flowing to the back surface 10b, thereby preventing contamination of the back surface 10b by resin.

The recess 13 having the wall 13a may be formed in the substrate 10 used in the semiconductor device 1C and the semiconductor device 1D, using a dicer, laser, or the like.

As the substrate 10 of the semiconductor device 1C and the semiconductor device 1D, the semiconductor chip 70A of FIG. 8A or 9C and the semiconductor chip 70B of FIG. 8B or 9C may be used, for example. Further, as the substrate 10 of the semiconductor device 1C and the semiconductor device 1D, the wafer 70 of FIG. 9A, the interposer 90 of FIG. 10, or the like may be used.

The recess 13 having the wall 13a may be formed in the substrate 10 used in the semiconductor device 1C and the semiconductor device 1D such that a corner where an inner wall surface and a bottom surface meet has a curved surface (rounded shape) in cross section. Further, the recess 13 may have a stepped shape in cross section. For example, the recess 13 may be formed such that the depth gradually increases toward the side surface 10c, may be formed such that the depth gradually decreases toward the side surface 10c, or may be formed such that the depth gradually increases and then decreases stepwise toward the side surface 10c. The recess 13 may have a tapered shape (for example, V shape) in cross section, or may have a curved shape (for example, U shape) in cross section.

The recess 13 having the wall 13a may be provided at the entire peripheral edge portion of the substrate 10 used for the semiconductor device 1C and the semiconductor device 1D, or may be disposed at a part of the peripheral edge portion (for example, at the edge portion along a given side or at a given corner).

According to the fourth embodiment, the recess 13 having the wall 13a is provided in the substrate 10, thereby preventing contamination of the back surface 10b of the substrate 10 by resin. Thus, it is possible to provide high-quality semiconductor device 1C and semiconductor device 1D.

Note that in this example, the recess 13 having the wall 13a is provided in the lower substrate 10. However, a recess 22 having a similar wall may be provided in the upper substrate 20. Even with this configuration, the resin that is caused to flow upon bonding flows into the recess 22, so that it is possible to reduce the speed and amount of the resin 30 that is pushed out to the outside of the substrate 10.

In the following, a fifth embodiment will be described.

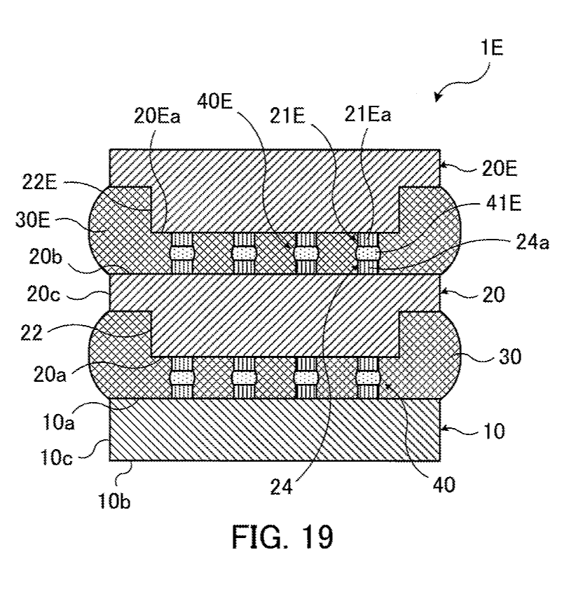

FIG. 19 illustrates an example of a semiconductor device according to a fifth embodiment. More specifically, FIG. 19 is a schematic cross-sectional view of a main part illustrating an example of a semiconductor device according to the fifth embodiment.

In the first to fourth embodiments, a structure is illustrated in which two substrates, namely, the substrate 10 and the substrate 20, are stacked and bonded. However, the number of substrates to be stacked is not limited to two.

For example, in a semiconductor device 1E illustrated in FIG. 19, a bonded structure including a substrate 10 and a substrate 20 as described in the first embodiment is provided, and another substrate 20E may be bonded to the substrate 20. As illustrated in FIG. 19, the substrate 20E that is bonded may have a recess 22E at an edge portion thereof. The substrate 20E may be bonded to the substrate 20 in the same way as the substrate 20 is bonded to the substrate 10 as described above.

The substrate 20E has terminals 21E including posts 21Ea on a surface (front surface) 20Ea facing the back surface 20b of the substrate 20. The posts 21Ea on the substrate 20E and posts 24a of terminals 24 on the back surface 20b of the substrate 20 are bonded with solder bonding portions 41E made of Sn—Ag solder or the like. The substrate 20E and the substrate 20 are electrically and mechanically connected through connection portions 40E. Resin 30E such as NCP, NCF, and so on is disposed between the substrate 20E and the substrate 20. The resin 30E enhances the bonding strength between the substrate 20E and the substrate 20.

Note that in this example, the single substrate 20E having the recess 22E is stacked on and bonded to the upper side of the substrate 20. However, one or more various types of substrates may be stacked on and bonded to the upper side of the substrate 20. Further, one or more various types of substrates may be stacked on and bonded to the lower side of the substrate 10, instead of the upper side of the substrate 20.

Further, various types of substrates may be stacked on the substrate 20 or under the substrate 10 described in the second to fourth embodiments and bonded thereto.

In the following, a sixth embodiment will be described.

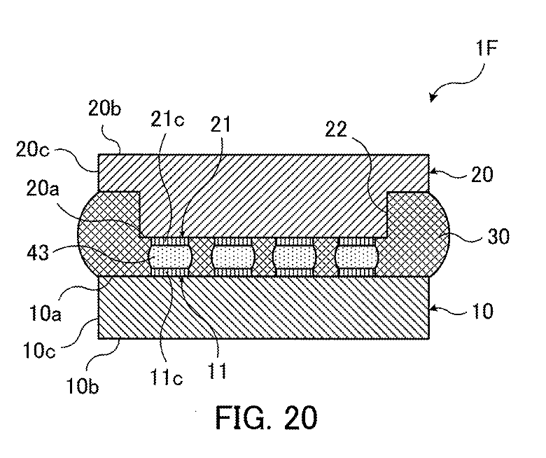

FIG. 20 illustrates an example of a semiconductor device according to a sixth embodiment. More specifically, FIG. 20 is a schematic cross-sectional view of a main part illustrating an example of a semiconductor device according to the sixth embodiment.

A semiconductor device 1F illustrated in FIG. 20 differs from the semiconductor device 1 of the first embodiment (FIG. 3) in that a substrate 10 having pads 11c as terminals 11 and a substrate 20 having pads 21c as terminals 21 are bonded with solder bonding portions 43.

The semiconductor device 1F is formed in the following manner, for example.

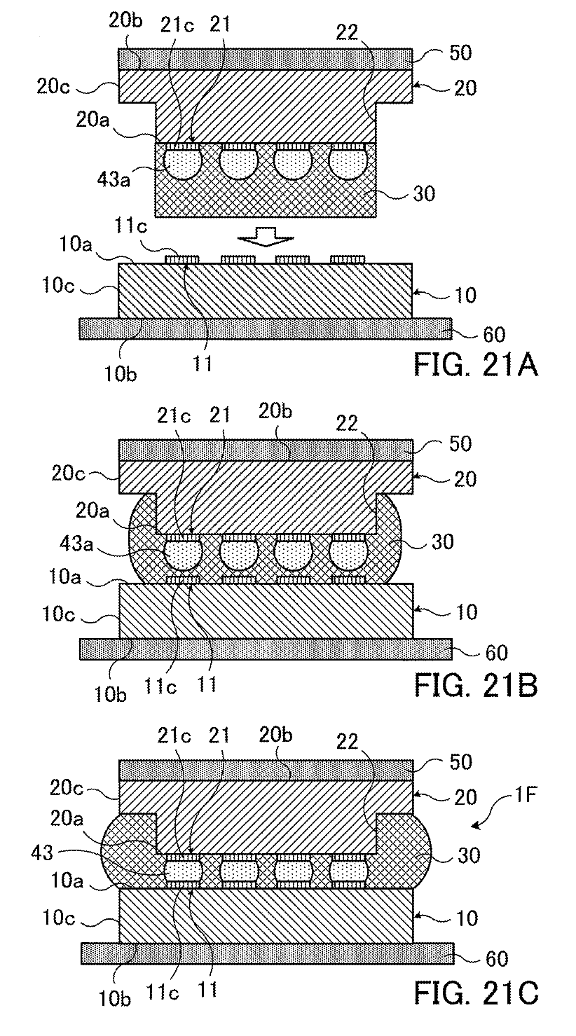

FIGS. 21A to 21C illustrate an example of a process of forming a semiconductor device according to the sixth embodiment. More specifically, FIG. 21A is a schematic cross-sectional view illustrating an example of a main part before substrate bonding; FIG. 21B is a schematic cross-sectional view illustrating an example of the main part during substrate bonding; and FIG. 21C is a schematic cross-sectional view illustrating an example of the main part after substrate bonding.

In this example, as illustrated in FIG. 21A, a substrate 20 having a recess 22 is prepared in which solder ball bumps 43a are disposed on pads 21c, and resin 30 is disposed on a front surface 20a. The substrate 20 is sucked and held by the head 50, and is disposed above the substrate 10 sucked and held on the stage 60 to face the substrate 10 in such a manner that the pads 21c (terminals 21) are aligned with the pads 11c (terminals 11). The substrate 20 is pressed toward the substrate 10 with pressure applied thereto, while being heated by a heating mechanism provided in the head 50, for example. In the process applying heat and pressure, as illustrated in FIGS. 21B and 21C, the substrate 10 and the substrate 20 are brought closer to each other, causing the resin 30 therebetween to flow. Also, as illustrated in FIG. 21C, the solder ball bumps 43a on the pads 21c come into contact with the pads 11c, so that the pads 21c and the pads 11c are bonded with the solder bonding portions 43. Further, the resin 30 is cured, and the cured resin 30 enhances the bonding strength between the substrate 10 and the substrate 20. Thus, the semiconductor device 1F is obtained.

In the semiconductor device 1F obtained by bonding the substrate 10 and the substrate 20 with the solder ball bumps 43a, the resin 30 that is caused to flow upon bonding flows into the recess 22 of the substrate 20, which reduces the speed and amount of the resin 30 that is pushed out to the outside of the substrate 10. Thus, it is possible to prevent the resin 30 from flowing along the side surface 10c of the substrate 10 to the back surface 10b, thereby preventing contamination of the back surface 10b by resin.

A connection between the substrate 10 and the substrate 20 in any of the semiconductor devices 1A, 1B, 1Ba, 1C, 1D, and 1E described in the second to fifth embodiments may be established by the pads 11c, the solder bonding portions 43, and the pads 21c as in the case of the sixth embodiment. Even in the case where a connection is established in this manner, it is possible to obtain the same effects as those described above.

The semiconductor devices 1, 1A, 1B, 1Ba, 1C, 1D, 1E, and 1F and the like (which may also be referred to as “electronic devices” or the like, other than “semiconductor devices”) described in the first to sixth embodiments may be used in various types of electronic apparatuses. Examples of such electronic apparatuses include computers (personal computers, super computers, servers, and so on), smartphones, mobile phones, tablet terminals, sensors, cameras, audio equipment, measuring equipment, inspection equipment, manufacturing equipment, and so on.

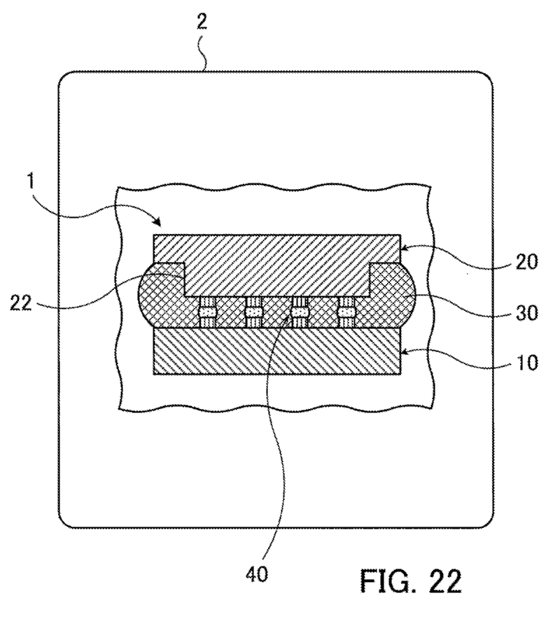

FIG. 22 illustrates an example of an electronic apparatus. More specifically, FIG. 22 is a schematic view illustrating an example of an electronic apparatus. As illustrated in FIG. 22, the semiconductor device 1 of FIG. 3 is mounted (embedded) in an electronic apparatus 2, which may be any of the various types of electronic apparatuses named above, for example.

In the semiconductor device 1, since the recess 22 is provided in the substrate 20, it is possible to prevent the resin 30 from flowing to the back surface 10b upon bonding to the substrate 10, thereby preventing contamination of the back surface 10b by resin. Thus, a high-quality semiconductor device 1 is provided, and a high-quality electronic apparatus 2 including such a semiconductor device 1 is provided.

Various types of electronic apparatuses including any of the other semiconductor devices 1A, 1B, 1Ba, 1C, 1D, 1E, and 1F and the like are also provided in the same manner.

According to the disclosed techniques, it is possible to prevent contamination of a substrate by resin that is used for bonding between substrates, and thus provide a high-quality semiconductor device. Further, it is possible to provide a high-quality electronic apparatus including such a semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a first substrate;
a second substrate facing the first substrate, and having a recess at a position corresponding to an edge portion of the first substrate;
a connection portion interposed between the first substrate and the second substrate, and electrically connecting the first substrate and the second substrate; and
resin disposed to remain between the first substrate and the second substrate, and covering the connection portion, part of the resin being present in the recess.

2. The semiconductor device according to claim 1, wherein the recess is provided at an edge portion of the second substrate.

3. The semiconductor device according to claim 1, wherein an inner wall surface and a bottom surface of the recess meet at a curved corner.

4. The semiconductor device according to claim 1, wherein a depth of the recess changes stepwise.

5. The semiconductor device according to claim 1, wherein a depth of the recess changes continuously.

6. The semiconductor device according to claim 1, wherein the recess extends to a side surface of the second substrate.

7. The semiconductor device according to claim 1, wherein the recess is provided on an inner side of a side surface of the second substrate, and has a wall on a side surface side of the second substrate.

8. The semiconductor device according to claim 1, wherein the recess is provided at an entire peripheral edge portion of the second substrate.

9. The semiconductor device according to claim 1, wherein the recess is provided at a part of a peripheral edge portion of the second substrate.

10. The semiconductor device according to claim 9, wherein the part includes whole or a part of an edge portion along one side of the second substrate.

11. The semiconductor device according to claim 9, wherein the part includes an edge portion at one corner of the second substrate.

12. A method of manufacturing a semiconductor device, comprising:
a first step of disposing a first substrate and a second substrate to face each other with resin interposed therebetween; and
a second step of bringing the first substrate and the second substrate closer to each other and electrically connecting the first substrate and the second substrate with a connection portion interposed therebetween;
wherein the second substrate has a recess at a position corresponding to an edge portion of the first substrate; and
wherein in the second step, the resin remains between the first substrate and the second substrate and covers the connection portion, and part of the resin is present in the recess.

13. The method of manufacturing a semiconductor device according to claim 12, further comprising:
before the first step, a step of preparing the second substrate with the resin thereon by forming, in a third substrate with the resin on a surface thereof, the recess by partially removing the resin and the third substrate;
wherein in the first step, the second substrate with the resin thereon is disposed on the first substrate such that a resin side of the second substrate faces the first substrate.

14. An electronic apparatus comprising:
a semiconductor device including
a first substrate,
a second substrate facing the first substrate, and having a recess at a position corresponding to an edge portion of the first substrate,
a connection portion interposed between the first substrate and the second substrate, and electrically connecting the first substrate and the second substrate, and
resin disposed to remain between the first substrate and the second substrate, and covering the connection portion, part of the resin being present in the recess.
